(19) United States
(12) Patent Application Publication
(10) Pub. No.: US 2022/0357532 A1
(43) Pub. Date: Nov. 10, 2022

(54) Optical Circuit Wafer

(71) Applicant: Nippon Telegraph and Telephone Corporation, Tokyo (JP)

(72) Inventors: Yoshiho Maeda, Tokyo (JP); Toru Miura, Tokyo (JP); Hiroshi Fukuda, Tokyo (JP)

(21) Appl. No.: 17/619,891

(22) PCT Filed: Jun. 17, 2019
(86) PCT No.: PCT/JP2019/023857

§ 371 Date: Dec. 16, 2021

(51) Int. Cl. G02B 6/42; G01R 31/28

(52) U.S. Cl. CPC G02B 6/4214; G01R 31/2886

(57) ABSTRACT

An embodiment optical circuit wafer includes a plurality of unit sections formed on a wafer. The plurality of unit sections are formed in each of first dies, second dies, and third dies. Further, each of the plurality of unit sections includes electrical pads formed in a common layout. Further, each of the plurality of unit sections includes optical input/output ports formed in a common layout. The input/output ports are, for example, grating couplers. Further, each of the plurality of unit sections includes optical circuits. The optical circuits have different circuit structures from one another.

### CROSS-REFERENCE TO RELATED APPLICATION

This application is a national phase entry of PCT Application No. PCT/JP2019/023857, filed on Jun. 17, 2019, which application is hereby incorporated herein by reference.

### TECHNICAL FIELD

The present invention relates to an optical circuit wafer in which a plurality of chips including optical circuits are formed.

### BACKGROUND

With an increase in optical communication traffic, reducing cost along with high speed and downsizing is desired for an optical transmitter and receiver. To reduce the size and cost of the optical transmitter and receiver, an optical circuit device including, for example, an optical filter and an optical modulator as component parts is desired that can be manufactured at low cost and a smaller size. Recently, as a technique for fabricating a small size optical circuit device at low cost, silicon photonics has been attracting attention, and research and development of optical integrated circuits using silicon photonics have been actively being conducted.

In the manufacture of the optical integrated circuits using this type of silicon photonics, the form of multi-project wafer (MPW) is often employed. Further, in many cases, various circuit elements included in a transceiver are fabricated together on the same wafer and are used by dicing the wafer into chips. In this way, when a plurality of types of optical integrated circuits are formed on a single wafer, unit sections thereof are different in size, or the unit sections have the same size but the positions of electrical pads and optical input/output ports in the unit sections are not uniform.

For example, in MPW, as shown in FIG. 6A, a plurality of dies 502, dies 503, and dies 504, which have the same die size but have different circuits formed thereon, are arranged on a wafer 501. A plurality of unit sections 502a shown in FIG. 6B are formed in each of the dies 502, and a plurality of unit sections 503a shown in FIG. 6C are formed in each of the dies 503, and a plurality of unit sections 504a shown in FIG. 6D are formed in each of the dies 504.

An optical integrated circuit 505a is formed in each of the unit sections 502a, and an optical integrated circuit 505b is formed in each of the unit sections 503a, and an optical integrated circuit 505c is formed in each of the unit sections 504a. Further, the arrangement (layout) of electrical pads 506 and optical input/output ports 507 in the unit sections 502a and the layout of electrical pads 506 and optical input/output ports 507 in the unit sections 503a and the layout of electrical pads 506 and optical input/output ports 507 in the unit sections 504a are different from one another. In each section, only the required numbers of the electrical pads and the optical input/output ports for the formed optical integrated circuit are arranged at given positions.

For example, in the manufacturing cost of the optical transmitter and receiver, a large proportion is occupied by mounting and test processes. In order to reduce the cost of the optical transmitter and receiver, it is desirable to test silicon photonics-based optical integrated circuits (optical circuit devices) on-wafer to select non-defective products, and then conduct module mounting.

As for a test method of the optical circuit devices described above, a typical method includes causing light from an external light source to enter the optical circuit device and evaluating insertion loss (IL) and operating characteristics. If the characteristics of an object to be measured include electrical inputs and outputs, the optical circuit device is contacted through an electrical probe to evaluate the electrical and optical characteristics.

When the evaluation (test) as described above is conducted on-wafer, it is desirable to use an automatic wafer prober having electrical and optical inputs and outputs in terms of reducing cost. For example, the automatic wafer prober as disclosed in non-patent literature 1 performs alignment with an optical circuit device to be tested with moving a wafer to be tested at an equal pitch, and after the position is aligned, electrical contact with the optical circuit device to be tested is achieved by using a probe card or a fixed probe. In general, an area containing the electrical pads, the optical input and output ports, and the circuit to be measured, which can be contacted at one time with the automatic wafer prober, is called a unit section. After such alignment and electrical contact, optical alignment with the optical circuit in the optical circuit device (optical alignment) is performed, and test light is introduced to the optical circuit device to conduct various tests.

### CITATION LIST

### Non-Patent Literature

Non-Patent Literature 1: Yamamoto Yousuke, A compact self-shielding prober for accurate measurement of on-wafer electron devices, IEEE Transactions on Instrumentation and Measurement, vol. 38, no. 6, pp. 1088-1093, 1989.

### SUMMARY

### Technical Problem

Here, as described above, the automatic wafer prober repeats the pitch movement that has been set and the test. It is thus desirable to make the layout of the electrical pads and the optical input/output ports connected to the circuit the same to evaluate the electrical and optical characteristics of any circuit in the wafer. However, as described above, in the manufacture of optical integrated circuits using silicon photonics, which often employs forms such as MPW, the unit sections are often different in size, or the positions of the electrical pads and the optical input/output ports in the unit sections are often not uniform. In such a condition, since the amount of movement and a contact position required for the automatic wafer prober are different on a unit section basis, continuous contact is not possible, which needs to correct the contact position each time.

Correcting the contact position often includes operations that are difficult to automate, such as modifying a probe card or a probe position, and changing a configuration file, which greatly prevents a cost reduction in automatic tests. Further, in a condition where a relative relationship regarding the electrical pads and the optical input/output ports is different among the unit sections, there may be large optical misalignment between different unit sections, which requires optical alignment in a wide range of hundreds of μm to several mm square and poses a problem of significant increase in time required for the test.

To solve the problems above, it is an object of the present invention to conduct a test of optical circuits in a short time.

### Means for Solving the Problem

An optical circuit wafer embodiment according to the present invention includes a plurality of unit sections formed on a wafer, an electrical pad formed in each of the plurality of unit sections, the electrical pads having a common layout, an optical input/output port formed in each of the plurality of unit sections, the optical input/output ports having a common layout, and an optical circuit formed in each of the plurality of unit sections.

In the above example structure of the optical circuit wafer, the electrical pad and the optical input/output port are arranged around the optical circuit in each of the plurality of unit sections.

In the above example structure of the optical circuit wafer, the plurality of unit sections are arranged at equal intervals.

In the above example structure of the optical circuit wafer, the optical circuit wafer includes a reflection portion optically connected to the optical input/output port.

In the above example structure of the optical circuit wafer, the optical circuit wafer includes a photodiode optically connected to the optical input/output port.

In the above example structure of the optical circuit wafer, a plurality of the optical input/output ports are formed in each of the plurality of unit sections, and any two of the optical input/output ports are optically connected to each other.

In the above example structure of the optical circuit wafer, the optical input/output port is a grating coupler.

### Effects of Embodiments of the Invention

As described above, according to embodiments of the present invention, since the electrical pads and the optical input/output ports are formed in the common layout in each of the plurality of unit sections formed on the wafer, the test of the optical circuits can be conducted in a shorter time.

### BRIEF DESCRIPTION OF THE DRAWINGS

FIG. 1A is a plan view showing a structure of an optical circuit wafer according to an embodiment of the present invention.

FIG. 1B is a plan view showing a portion of a structure of an optical circuit wafer according to an embodiment of the present invention.

FIG. 1C is a plan view showing a portion of a structure of an optical circuit wafer according to an embodiment of the present invention.

FIG. 1D is a plan view showing a portion of a structure of an optical circuit wafer according to an embodiment of the present invention.

FIG. 2A is a plan view showing a structure of an optical circuit wafer according to an embodiment of the present invention.

FIG. 2B is a plan view showing a portion of a structure of an optical circuit wafer according to an embodiment of the present invention.

FIG. 3 is a plan view showing a portion of a structure of an optical circuit wafer according to an embodiment of the present invention.

FIG. 4A is an explanatory diagram for illustrating a test method by using an optical circuit wafer according to an embodiment of the present invention.

FIG. 4B is an explanatory diagram for illustrating a test method by using an optical circuit wafer according to an embodiment of the present invention.

FIG. 5A is a configuration diagram showing a portion of a structure of an optical circuit wafer according to an embodiment of the present invention.

FIG. 5B is a configuration diagram showing a portion of a structure of an optical circuit wafer according to an embodiment of the present invention.

FIG. 5C is a configuration diagram showing a portion of a structure of an optical circuit wafer according to an embodiment of the present invention.

FIG. 6A is a plan view showing the structure of a conventional optical circuit wafer.

FIG. 6B is a plan view showing a portion of a structure of a conventional optical circuit wafer.

FIG. 6C is a plan view showing a portion of a structure of a conventional optical circuit wafer.

FIG. 6D is a plan view showing a portion of a structure of a conventional optical circuit wafer.

### DETAILED DESCRIPTION OF ILLUSTRATIVE EMBODIMENTS

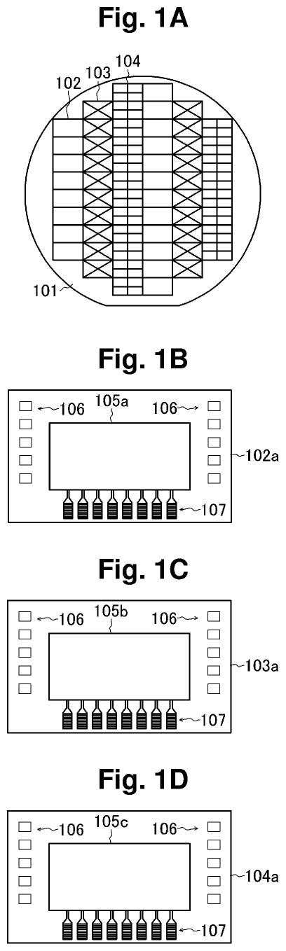

An optical circuit wafer according to an embodiment of the present invention will now be described with reference to FIG. 1A, FIG. 1B, FIG. 1C, and FIG. 1D.

This optical circuit wafer includes a plurality of unit sections 102a, 103a, and 104a formed on a wafer 101. Further, each of the plurality of unit sections 102a, 103a, and 104a includes electrical pads 106 formed in a common layout. In other words, the arrangement and the number of the electrical pads 106 are common for each of the plurality of unit sections 102a, 103a, and 104a.

Further, each of the plurality of unit sections 102a, 103a, and 104a includes optical input/output ports 107 formed in a common layout. In other words, the arrangement and the number of the optical input/output ports 107 are common for each of the plurality of unit sections 102a, 103a, and 104a. The optical input/output ports 107 are, for example, grating couplers. It is noted that the optical input/output ports 107 are not limited to the grating couplers, and any optical coupling element that has a structure of being able to be optically coupled.

Further, the plurality of unit sections 102a, 103a, and 104a include optical circuits 105a, 105b, and 105c, respectively, formed in each unit section. The optical circuits 105a, 105b, and 105c have different circuit structures from one another.

Here, in each of the plurality of unit sections 102a, 103a, and 104a, the electrical pads 106 and the optical input/output ports 107 are arranged around the optical circuits 105a, 105b, and 105c. Further, the plurality of electrical pads 106 are arranged in a row in each arrangement area. In the examples shown in FIG. 1B, FIG. 1C, and FIG. 1D, electrical pad arrangement areas are provided in the horizontal direction of the paper in the figures and on both sides of the optical circuits 105a, 105b, and 105c. In each of the arrangement areas, the plurality of electrical pads 106 are arranged in a row in the vertical direction of the paper.

Further, the plurality of optical input/output ports 107 are arranged in a row in this arrangement area. In the examples shown in FIG. 1B, FIG. 1C, and FIG. 1D, optical input/output port arrangement areas are provided on the lower sides of the paper in the figures of the optical circuits 105a, 105b, and 105c. In this arrangement area, the plurality of optical input/output ports 107 are arranged in a row in the horizontal direction of the paper.

Further, each of the unit sections 102a, the unit sections 103a, and the unit sections 104a are arranged at equal intervals. In addition, the relative positional relationship between the electrical pads 106 and the optical input/output ports is designed so that the operating range of an electrical probe by which the electrical pads 106 are contacted and the operating range of an optical probe by which the optical input/output ports are optically coupled do not interfere with each other.

It is noted that dies 102, dies 103, and dies 104, which have the same size, are formed on the wafer tot. The dies 102, the dies 103, and the dies 104 are, for example, unit areas that are exposed in one shot of a reduced projection exposure apparatus in a lithography process, which is in the middle of manufacturing. A plurality of the dies 102, a plurality of the dies 103, and a plurality of the dies 104 are formed on the wafer 101. The plurality of unit sections 102a are formed on the dies 102, and the plurality of unit sections 103a are formed on the dies 103, and the plurality of unit sections 104a are formed on the dies 104.

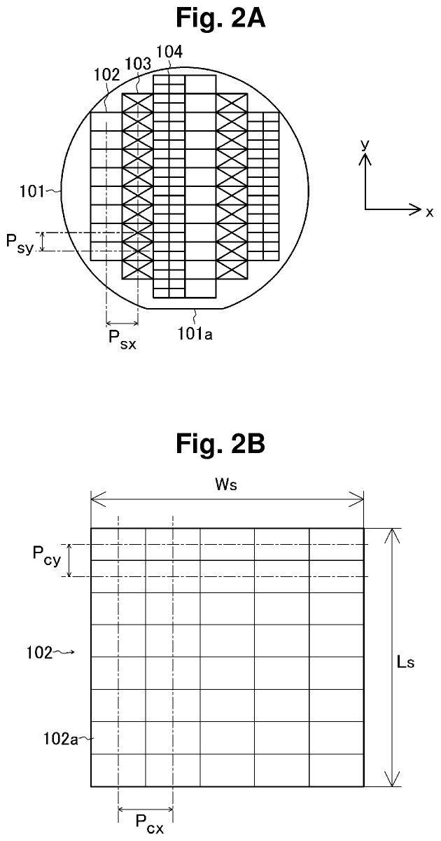

As shown in FIG. 2A and FIG. 2B, x is a direction parallel to orientation flat 102a and y is a direction perpendicular to the orientation flat 102a in the plane of the wafer tot. Further, the size of the dies 102 is Ws in length in the x-direction and Ls in length in the y-direction. The dies 103 and the dies 104 have the same size as that of the dies 102. Further, the size of the unit sections 102a is We in length in the x-direction and Lc in length in the y-direction. The unit sections 103a and 104a have the same size as that of unit sections 102a.

Further, as for an arrangement interval (pitch) of the dies 102, the dies 103, and the dies 104 on the wafer 101, Psx is a pitch in the x-direction and Psy is a pitch in the y-direction. Further, as for pitches of the unit sections 102a within each of the dies 102, Pcx is a pitch in the x-direction and Pcy is a pitch in the y-direction. The unit sections 103a and 104a have the same pitches as those of the unit sections 102a.

For example, when the number of the unit sections 102a formed in each of the dies 102 is lx in the x-direction and ly in the y-direction, the relationship between Pcx and Psx and the relationship between Pcx and Pcy are represented by the following Expression (1) and Expression (2) respectively. This is the same for the unit sections 103a in the dies 103 and the unit sections 104a in the dies 104.

Psx=Pcx×lx, where lx is an integer (1)

Psy=Pcy×ly, where ly is an integer (2)

Further, Lc and Wc, which are the dimensions of the unit sections 102a, and Ls and Ws, each of which is the length of each side of the dies 102, are represented by the following Expressions (3) and (4).

n×Lc=Ls, where n is an integer (3)

m×Wc=Ws, where m is an integer (4)

If the conditions shown in the relationships described above are satisfied, there is no limit to the number of the unit sections in each die.

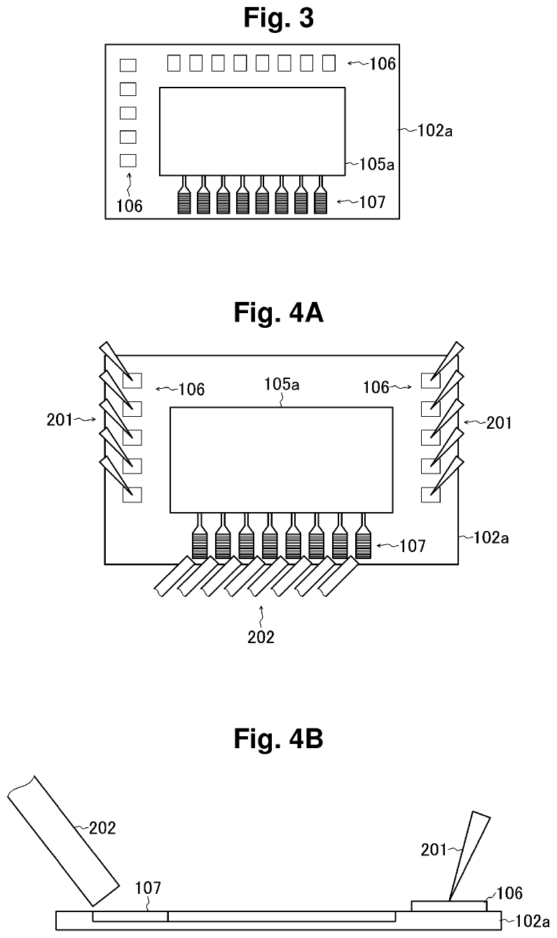

It is noted that the layout of the electrical pads 106 and the layout of the optical input/output ports 107 can also be configured as shown in FIG. 3. The number and the arrangement of the electrical pads 106 and the number and the arrangement of the optical input/output ports 107 need to be common for all the dies formed on the wafer 101, and are not limited to the examples described above.

According to the above embodiment, all the electrical pads on the wafer are arranged at equal intervals on a plurality of axes (virtual axes). This is the same for the optical input/output ports. Therefore, since the optical circuit wafer according to the embodiment can contact the electrical pads and the optical input/output ports by moving an automatic wafer prober at an equal pitch, modifying the contact position each time is not needed, and this makes it possible to conduct a fully automatic test and reduce the test time.

Next, a test method of the optical circuit wafer according to the embodiment will now be described with reference to FIG. 4A and FIG. 4B.

First, as shown in FIG. 4A, each of the electrical pads 106 is contacted with an electrical probe array 201 to test the electrical characteristics. Optical input/output to/from each of the optical input/output ports 107 is performed by using an optical fiber array 202.

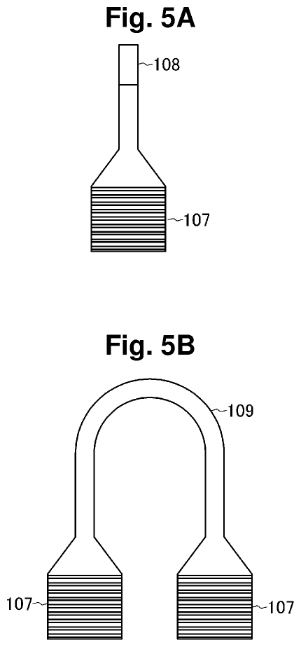

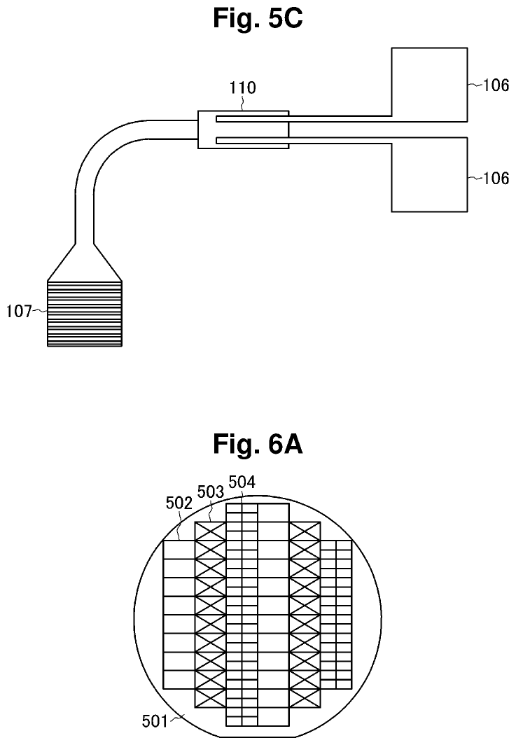

Optical alignment between each of the optical input/output ports 107 and the optical fiber array 202 are performed, for example, as shown in FIG. 5A, by fabricating a reflection portion 108 that is optically connected to each of the optical input/output ports 107 in a portion of each of the optical input/output ports 107 and monitoring the return light. The reflection portion 108 is equipped in any number of the optical input/output ports 107, including all the optical input/output ports 107.

Further, the optical alignment between each of the optical input/output ports 107 and the optical fiber array 202 are performed, for example, as shown in FIG. 5B, by optically connecting two adjacent optical input/output ports 107 by using an optical waveguide 109, causing light to enter one of the optical input/output ports 107, and monitoring the light emitted from the other one of the optical input/output ports 107. The optical waveguide 109 is equipped in any number of the optical input/output ports 107, including all the optical input/output ports 107.

Further, the optical alignment between each of the optical input/output ports 107 and the optical fiber array 202 can also be performed, for example, as shown in FIG. 5C, by using a photodiode 110 that is optically connected to the optical input/output ports 107. The photodiode no is, for example, a germanium photodiode. The light having entered the optical input/output ports 107 is photoelectrically converted by the photodiode no. The electrical pads 106 are electrically connected to the photodiode no, and an electrical signal photoelectrically converted by the photodiode 110 can be output from the electrical pads 106. The optical alignment between each of the optical input/output ports 107 and the optical fiber array 202 is performed by contacting the electrical pads 106 with the electrical probe array 201 and monitoring the electrical signal described above with the automatic wafer prober. The photodiode 110 is equipped in any number of the optical input/output ports 107, including all the optical input/output ports 107.

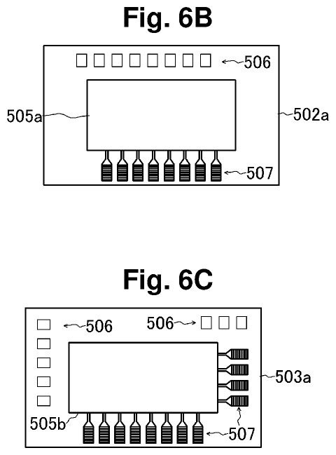

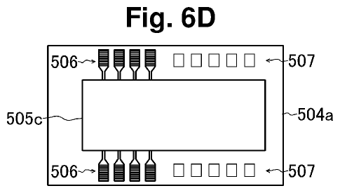

As described in the conventional technique using FIG. 6A, FIG. 6B, FIG. 6C, and FIG. 6D, if the positions of the optical input/output ports are different for each die or unit section on the wafer, it is necessary to scan optical fibers (optical fiber arrays) in a wide range to perform alignment. In contrast, in this embodiment, as described above, even if the wafer is moved by the automatic wafer prober to change an object to be measured, the optical input/output ports exist in a position within a range of several μm from positioning accuracy by the automatic wafer prober. If the position of the electrical probe relative to the optical probe is fixed in the prober, the test of the optical circuit wafer according to this embodiment requires only a fine alignment of several μm to several tens of μm square for the optical probe, and thus can reduce the time for optical alignment.

As described above, according to embodiments of the present invention, the electrical pads and the optical input/output ports are formed in the common layout in each of the plurality of unit sections formed on the wafer, and this allows the test of optical circuits to be conducted in a shorter time. According to embodiments of the present invention, the positions and the numbers of the electrical pads and the optical input/output ports in all the unit sections on the wafer are uniform and the pitches are even, which makes it possible to simplify optical alignment, shorten the time for alignment, and conduct automatic measurement by using the automatic wafer prober, and thus achieves shortened test time and reduced cost.

It is noted that the present invention is not limited to the embodiment described above, and it is clear that many modifications and combinations are feasible by those skilled in this art within the technical concept according to the present invention.

### REFERENCE SIGNS LIST

101 Wafer
102a Orientation flat
102 Die
102a Unit section
103 Die
103a Unit section
104 Die
104a Unit section
105a, 105b, 105c Optical circuit
106 Electrical pad

1.-7. (canceled)

8. An optical circuit wafer comprising:
a plurality of unit sections;
an electrical pad in each of the plurality of unit sections, the electrical pads having a common layout;
an optical input/output port in each of the plurality of unit sections, the optical input/output ports having a common layout; and
an optical circuit in each of the plurality of unit sections.

9. The optical circuit wafer of claim 8, wherein the electrical pad and the optical input/output port are arranged around the optical circuit in each of the plurality of unit sections.

10. The optical circuit wafer of claim 8, wherein the plurality of unit sections are arranged at equal intervals.

11. The optical circuit wafer of claim 8 further comprising:
a reflection portion optically connected to the optical input/output port in each of the plurality of unit sections.

12. The optical circuit wafer of claim 8 further comprising:
a photodiode optically connected to the optical input/output port in each of the plurality of unit sections.

13. The optical circuit wafer of claim 8, wherein the optical input/output port is one of a plurality of optical input/output ports in each of the plurality of unit sections, and any two of the optical input/output ports are optically connected to each other.

14. The optical circuit wafer of claim 8, wherein the optical input/output port in each of the plurality of unit sections is a grating coupler.

15. An optical circuit wafer comprising:
a first die section comprising a first optical circuit, first electrical pads, and first optical input/output ports; and
a second die section comprising a second optical circuit, second electrical pads, and second optical input/output ports, wherein the first die section has the same size as the second die section, wherein the first optical circuit has a different circuit structure from the second optical circuit, wherein the first electrical pads have the same relative positions in the first die section as the second electrical pads have in the second die section, and wherein the first optical input/output ports have the same relative positions in the first die section as the second optical input/output ports have in the second die section.

16. The optical circuit wafer of claim 15, wherein the first electrical pads have the same relative sizes in the first die section as the second electrical pads have in the second die section.

17. The optical circuit wafer of claim 15, wherein the first electrical pads have the same relative pitches in the first die section as the second electrical pads have in the second die section.

18. The optical circuit wafer of claim 15, wherein the first electrical pads and the second electrical pads are arranged in a first direction, and the first optical input/output ports and the second optical input/output ports are arranged in a second direction, the second direction different from the first direction.

19. A method comprising:
forming a first optical circuit and a second optical circuit on a wafer, the first optical circuit having a different circuit structure from the second optical circuit;
forming first electrical pads and first optical input/output ports for the first optical circuit; and
forming second electrical pads and second optical input/output ports for the second optical circuit, the first electrical pads and the second electrical pads having a common layout, the first optical input/output ports and the second optical input/output ports having a common layout.

20. The method of claim 19, wherein the first optical circuit is formed in a first unit area that is exposed in a first lithography process, and the second optical circuit is formed in a second unit area that is exposed in a second lithography process.

21. The method of claim 19 further comprising:
connecting one of the first optical input/output ports to one of the second optical input/output ports.

22. The method of claim 19 further comprising:
testing the first optical circuit with a wafer prober; and
testing the second optical circuit with the wafer prober, wherein a contact position for the wafer prober when testing the first optical circuit is the same as the contact position for the wafer prober when testing the second optical circuit.
